(19) United States
(12) Patent Application Publication
(10) Pub. No.: US 2005/0214975 A1
(43) Pub. Date: Sep. 29, 2005

(54) Method of fabricating the planar encapsulated surface

(76) Inventors: Denny Chao, Tao Yuan Hsien (TW); Cyril Cheng, Hsinchu City (TW); Nico Lee, Hsinchu City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/861,358

(22) Filed: Jun. 7, 2004

(30) Foreign Application Priority Data
Mar. 26, 2004 (TW) 93108242

(51) Int. Cl. H01L 21/56

(52) U.S. Cl. 438/107; 438/126

(57) ABSTRACT

A method of fabricating the planar encapsulated surface is described. The substrate is provided, wherein a plurality of packaging units are formed thereon. The lower surface of the substrate is etched to form a trench between every two packaging units. The encapsulation adhesive material is filled to cover the lower surface of the substrate and the trench. A heatproof board is placed on the surface of the encapsulation material and the thermal process is performed to spread the encapsulation adhesive material out uniformly. The heatproof is removed to obtain a packaging structure having the planar surface.

### FIELD OF THE INVENTION

The present invention relates to a method of fabricating the packaging, and more particularly to a method for planarizing the encapsulation adhesive material.

### BACKGROUND OF THE INVENTION

In packaging technologies of electronic elements, the prior art usually utilizes chip on board (COB) technology to achieve the packaging object. As a result of COB packaging technology has disadvantages with complex wiring process, low yield, large dimensions and whole process complicated, etc., for examples, flip chip and tape carrier package (TCP).

Another conventional packaging technology is shown in FIG. 1A and FIG. 2B, a wafer 10 comprises is a plurality of packaging units 12 thereon, and a glass substrate is covered over the wafer 10 by adhering a glue layer 14 to provide a sandwich packaging structure; and a trench 18 is etched between every two packaging units 12 on the back of the wafer 10 to connect the line 20 from the front to the back of the packaging unit 12. Finally, the encapsulation adhesive material 22 is filled to protect the line 20 to finish the initial wafer packaging structure. After finishing the initial wafer packaging structure, the photoresist is formed on the back of the wafer and implanted the solders processes, etc., and then the packaging structure is diced into the individual package structures. However, due to the trench 18 is formed on the back of the wafer 10, it will result in the poor planar surface of the filled encapsulation adhesive material, and be a potential failure in the next manufacturing process. Therefore, as previous technology is to fill the encapsulation adhesive material as to adhere a glass board 24 on the back of the wafer 20 by using the viscosity of encapsulation adhesive material 22 to achieve the request of planar surface. However, the way of increasing glass board 24 is not only to increase the thickness and the weight of packaging structure, which is diverged from the trend of the thinness and lighter, but also disadvantage for the dicing process and increasing the manufacturing cost. As the cost of glass board is increased that the manufacturing cost is also increased.

According to the problems above mentioned, the present invention provides a method of fabricating the packaging, and more particularly to a method for planarizing the encapsulation adhesive material.

### SUMMARY OF THE INVENTION

The primary object of the present invention is to provide a method for fabricating the planar encapsulated surface, wherein the encapsulation adhesive material is uniformly spread out along the surface by utilizing the heatproof board, and the heatproof board is removed in order to provide an extremely planar surface of packaging structure.

Another object of the present invention is to provide a method for planarizing the encapsulation adhesive material, without using a glass board placed on the encapsulation adhesive material to obtain the planar surface. It is not only to provide a planar encapsulated surface, but also to be able to maintain the request of thinner and lighter of packaging structure.

Another object of the present invention is to provide a method for planarizing the encapsulation adhesive material, improving the disadvantages of dicing and increasing the cost due to place glass board.

Another object of the present invention is to provide a encapsulation method without the glass board, wherein a heatproof board is used to perform the planarizatoin process without using the expensive glass board to reduce the manufacturing cost.

In accordance with the present invention, a method for fabricating the planar encapsulated surface is provided, comprising the steps of: first, providing a substrate, wherein a plurality of packaging units are formed on the substrate; then etching the lower surface of the substrate to form a trench between every two packaging units; forming an encapsulation adhesive material on the lower surface of the substrate and filing the trench; covering a heatproof board on the surface of the encapsulation adhesive material, and performing the thermal processing; removing the heatproof to obtain a planar encapsulated structure.

### BRIEF DESCRIPTION OF THE DRAWINGS

In the accompanying drawings forming a material part of this description, there is shown:

FIG. 1A and FIG. 1B are the cross-sectional views of encapsulation structures with planar structure in accordance with the prior art.

FIGS. 2 to 6 are the cross-sectional views showing the steps of fabricating wafer packaging in accordance with the present invention.

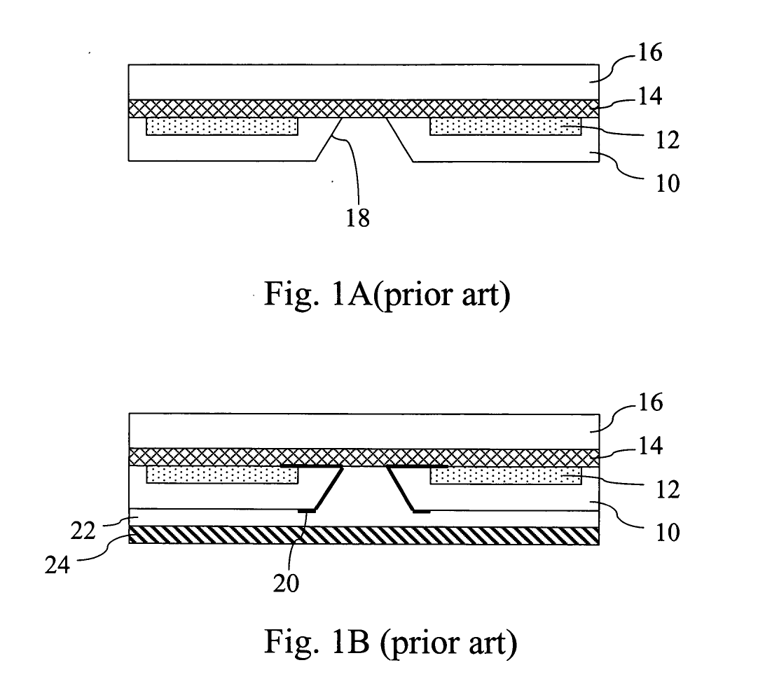

### DETAILED DESCRIPTION OF THE DRAWINGS

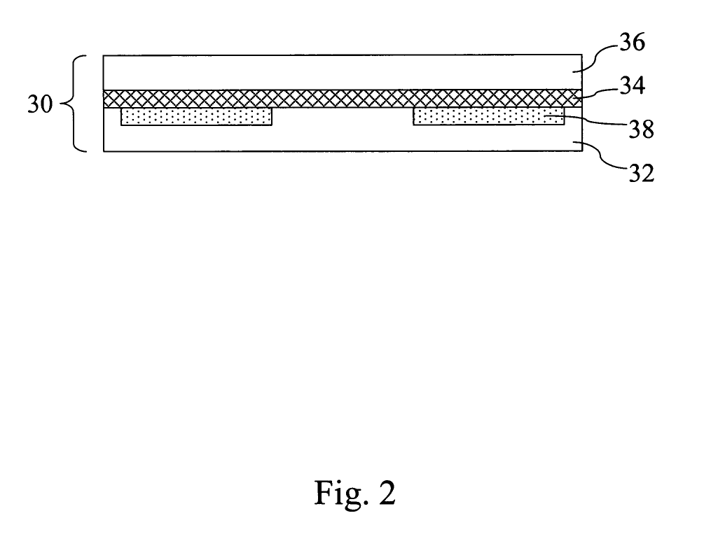

The present invention discloses a method of planarizing the encapsulation adhesive material, wherein it can be applied in wafer scale technologies. Referring to FIGS. 2 to 6, showing the steps of fabricating wafer packaging in accordance with the prevent invention. The method of planarizing the encapsulation adhesive material comprises the steps: first, as shown in FIG. 2, a substrate 30 is provided, wherein the substrate 30 generally comprises a wafer 32 having a plurality packaging units 38 thereon, and a transparent substrate 36 is adhered on the wafer 32 by the adhesive layer 34. The transparent substrate 36 is usually a glass material. The packaging units 38 on the wafer 32 are diced into individual dies. The substrate 30 can also be a wafer.

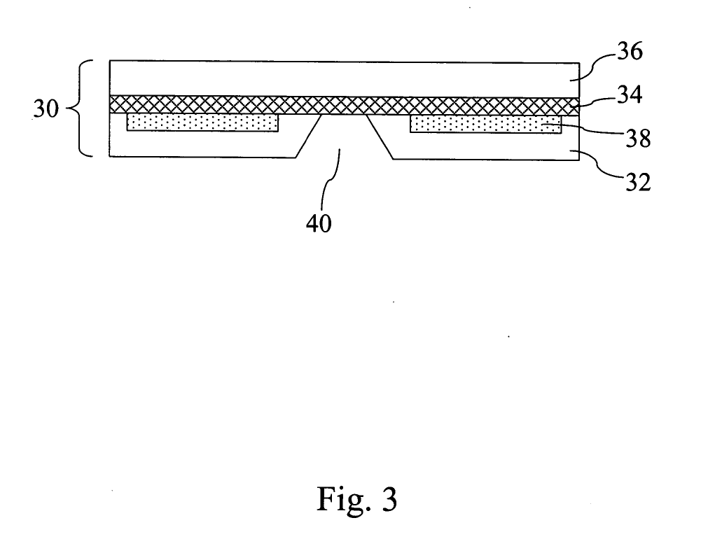

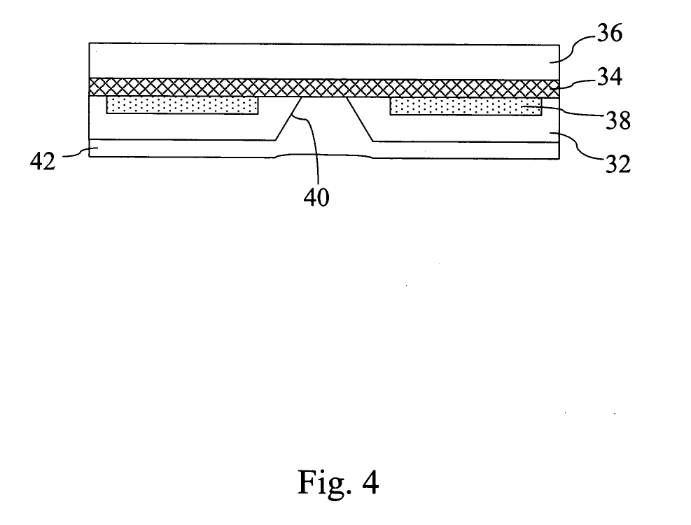

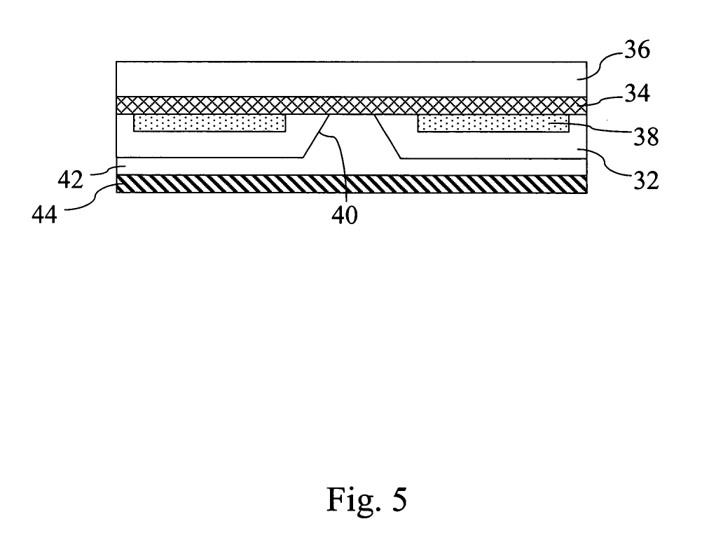

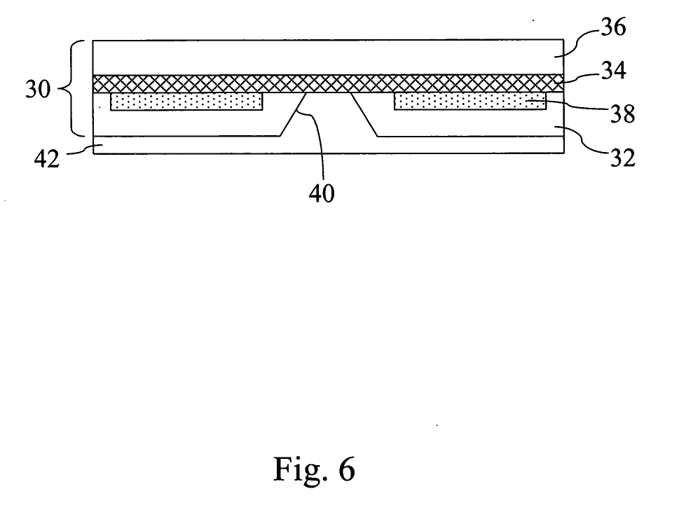

As shown in FIG. 3, the lower surface of the substrate is etched through the wafer 32 to form a trench 40 between every two packaging units 38. After fabricating the trench 40, shown in FIG. 4, an encapsulation adhesive material 42 is formed under the lower surface of the wafer 32 to cover the lower surface of the wafer 32 and to fill the trenches 40. As shown in FIG. 5, a heatproof board 44 is covered the surface of the encapsulation adhesive material 42 and the thermal process is performed, wherein the heatproof board 44 is generally a metal board. After finishing the thermal process, the etching process is performed, wherein the etching sources can be liquid or gas which the etching sources is entered into the interface between the heatproof board 44 and the encapsulation adhesive material 42 to loose the interface. After finishing the etching process, the heatproof board 44 is removed to finish the planarization process of the packaging structure to obtain the encapsulation adhesive material 42 with planar structure and the structure of the wafer scale packaging shown in FIG. 6, in order to perform the steps as requests by the process such as the coating photoresist process, the development process, the implantation process for solders and dicing.

The method mentioned above, because the recess portion is easily formed in the trench 40 of the encapsulation adhesive material 42, a heatproof board 44 is placed on the encapsulation adhesive material 42 after filling the encapsulation adhesive material 42. The adhesive material is spread out uniformly along the heatproof board 44 by capillarity. As the result of the poor adhesion between the adhesive material 42 and the metal material of heatproof board 44 and thermal expansion with cold contraction effect of heating, it results the interface between the adhesive material 42 and the heatproof board 44 to be loosed. Moreover, enchant is able to enter along the interface and work when etching. Therefore, the heatproof board 44 is easily removed to obtain the planarization of encapsulation adhesive material 42 without placing the glass board at the back of the wafer as the prior art.

Furthermore, while the back of the wafer 32 is required extremely planar, the planar layer is formed at the surface of the encapsulation adhesive material 42 after removing the heatproof board 44, wherein epoxy resin, acrylic resin or any kind of dielectric materials are coated on the surface of the encapsulation adhesive material 42 by spin coating.

According to the present invention, a heatproof board is placed on the surface of the adhesive material filled at the back of the wafer to spread out the adhesive material uniformly along the surface of the heatproof board, and then the heatproof board is removed to be able to provide an extremely planar encapsulation surface. It would be of great benefit for the next fabrication process without placing the glass board. Therefore, the present invention is not only to provide an extremely planar surface of packaging structure, but also not to increase the thickness and weight of packaging structure to keep the requests of thinness and light, and it also improves the disadvantages of the prior art which the glass board is placed and it results that the dicing cost is increased.

The foregoing description of the preferred embodiments of this invention has been presented for purposes of illustration and description. Obvious modifications or variations are possible in light of the above teaching. The embodiments were chosen and described to provide the best illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

1. A method of fabricating the planar encapsulated surface, comprising the steps:
providing a substrate, wherein a plurality of packaging units are formed on said substrate;
etching the lower surface of said substrate to form a trench between every two said packaging units;
forming an encapsulation adhesive material on the lower surface of said substrate and filling said trench;
covering a heatproof board on the surface of said encapsulation adhesive material and performing a thermal process; and
removing said heatproof board.

2. The method of fabricating the planar encapsulated surface according to claim 1, wherein further comprising an etching process after the step of performing the thermal process.

3. The method of fabricating the planar encapsulated surface according to claim 1, wherein said heatproof board is a metal board.

4. The method of fabricating the planar encapsulated surface according to claim 1, wherein further comprising a step of forming a planar layer on the surface of said encapsulation adhesive material after the step of removing said heatproof board.

5. The method of fabricating the planar encapsulated surface according to claim 4, wherein the material of said planar layer is selected from one of epoxy resin, acrylic resin and any kind of dielectric materials.

6. The method of fabricating the planar encapsulated surface according to claim 4, wherein said planar layer is formed by spin coating.

7. The method of fabricating the planar encapsulated surface according to claim 1, wherein said substrate is a wafer.

8. The method of fabricating the planar encapsulated surface according to claim 1, wherein said substrate comprises a wafer, wherein a transparent substrate is adhered on said wafer.

9. The method of fabricating the planar encapsulated surface according to claim 8, wherein said transparent substrate is a glass material.
